(19) United States
(12) Patent Application Publication
(10) Pub. No.: US 2009/0206840 A1
(43) Pub. Date: Aug. 20, 2009

(54) MAGNETIC RESONANCE RECEIVE COIL ARRAY INTEGRATED INTO WALL OF SCANNER BORE

(75) Inventors: Johan A. Overweg, Uelzen (DE); Daniel Wirtz, Hamburg (DE)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N. V., Eindhoven (NL)

(21) Appl. No.: 12/305,442

(22) PCT Filed: Jun. 19, 2007
(86) PCT No.: PCT/US07/71504

§ 371 Date: Dec. 18, 2008

Related U.S. Application Data
(60) Provisional application No. 60/805,501, filed on Jun. 22, 2006.

(51) Int. Cl. G01R 33/36

(52) U.S. Cl. 324/322

(57) ABSTRACT

In a magnetic resonance scanner, a radio frequency transmit coil (30, 30′) includes a plurality of parallel rods rungs (32, 32′, 32″) at least partially surrounding an examination region. The radio frequency transmit coil is configured to transmit radio frequency energy into the examination region at or near a magnetic resonance frequency. A plurality of magnetic resonance receive coils (40) are disposed with the radio frequency transmit coil. For decoupling, each magnetic resonance receive coil is positioned substantially centered on a proximate one rod or rung or proximate plurality of neighboring rods or rungs of the radio frequency transmit coil.

The present application relates to the magnetic resonance arts. It finds particular application in parallel magnetic resonance imaging, and is described with particular reference thereto. The following finds more general application in magnetic resonance scanners for use in imaging, spectroscopy, and so forth.

Parallel imaging techniques, such as sensitivity encoding (SENSE) imaging, provide certain advantages. These imaging techniques employ an array of magnetic resonance receive coils, which are typically placed on top of the patient. Such an arrangement provides good coupling and hence good signal-to-noise ratio. However, the array of magnetic resonance receive coils cannot be assembled until the patient is available and positioned on the patient support just prior to imaging. This adversely impacts workflow efficiency and speed. Moreover, placement of the magnetic resonance receive coils on the patient is objectionable to some patients. Still further, the coils disposed on the patient are prone to being shifted or jostled by patient movement.

Some of these disadvantages can be overcome by arranging the magnetic resonance receive coils as a pre-formed array that is disposed on the patient. For example, the coils can be supported by a common support substrate, which may be flexible or jointed to permit some conformance with the patient's shape or to promote comfortable positioning of the coil-supporting substrate on the patient. Using such a common substrate reduces patient setup time and simplifies placement of the magnetic resonance receive coils on the patient. However, these approaches retains some disadvantages—patient setup time is still adversely affected by the requirement that the coils be placed onto the patient just prior to imaging, and some patients can be expected to object to placement of the coil-supporting substrate on the patient. Moreover, the integration of the entire coil array onto a common substrate can exasperate the problem of shifting or jostling due to patient movement, since with a common substrate more than one coil, or the entire coil array, may be shifted or jostled.

The present application provides improvements which overcome the above-referenced problems and others.

In accordance with one aspect, a magnetic resonance scanner is disclosed. A radio frequency transmit coil includes a plurality of parallel rods or rungs at least partially surrounding an examination region. The radio frequency transmit coil is configured to transmit radio frequency energy into the examination region at or near a magnetic resonance frequency. A plurality of magnetic resonance receive coils are disposed with the radio frequency transmit coil. Each magnetic resonance receive coil overlaps and is positioned substantially centered on a proximate one rod or rung or proximate plurality of neighboring rods or rungs of the radio frequency transmit coil.

In accordance with another aspect, a magnetic resonance scanner is disclosed. A scanner housing defines a bore having a bore wall. An examination region is located within the bore. A main magnet disposed in the scanner housing generates a static magnetic field in the examination region. Magnetic field gradient coils are configured to selectably superimpose magnetic field gradients on the static magnetic field in the examination region. A plurality of generally planar magnetic resonance coil loops are disposed on or in the bore wall.

In accordance with another aspect, a magnetic resonance scanner is disclosed. A radio frequency transmit coil substantially surrounds an examination region and is configured to transmit radio frequency energy at or near a magnetic resonance frequency into the examination region. A plurality of substantially planar magnetic resonance receive coils are arranged close to the radio frequency transmit coil. Each generally planar magnetic resonance receive coil is positioned respective to the radio frequency transmit coil such that a net flux of electric and magnetic fields passing through the receive coil is small.

One advantage resides in improved workflow efficiency and speed in magnetic resonance scanning.

Another advantage resides in improved patient comfort.

Another advantage resides in improved positional stability for magnetic resonance receive coils used in parallel magnetic resonance scanning.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

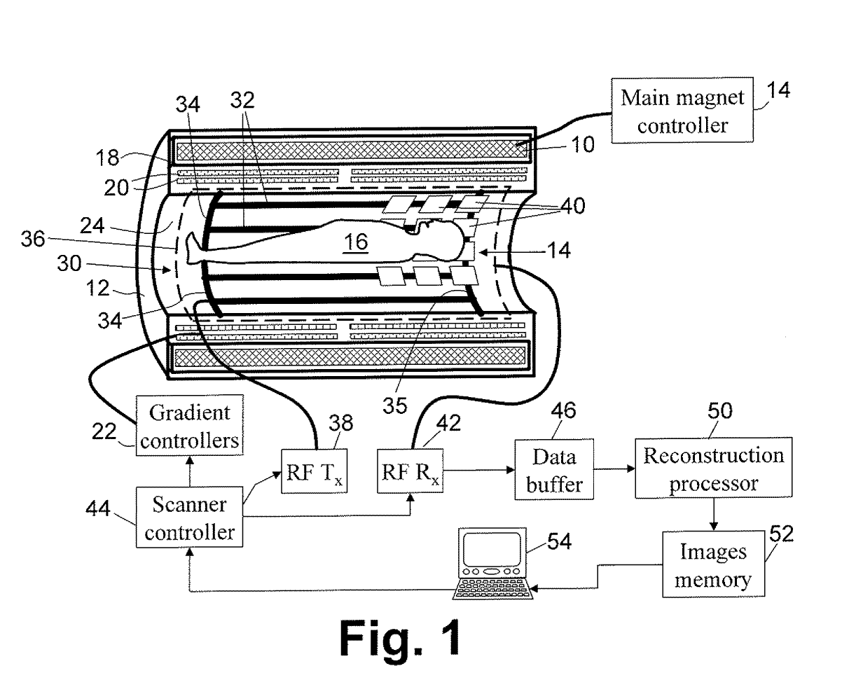

FIG. 1 diagrammatically shows a magnetic resonance scanner including a birdcage radio frequency coil for transmitting radio frequency energy at or near a magnetic resonance frequency during the transmit phase, and an array of generally planar magnetic resonance receive coils mounted on the wall of the scanner bore for receiving magnetic resonance signals during the receive phase of the magnetic resonance sequence.

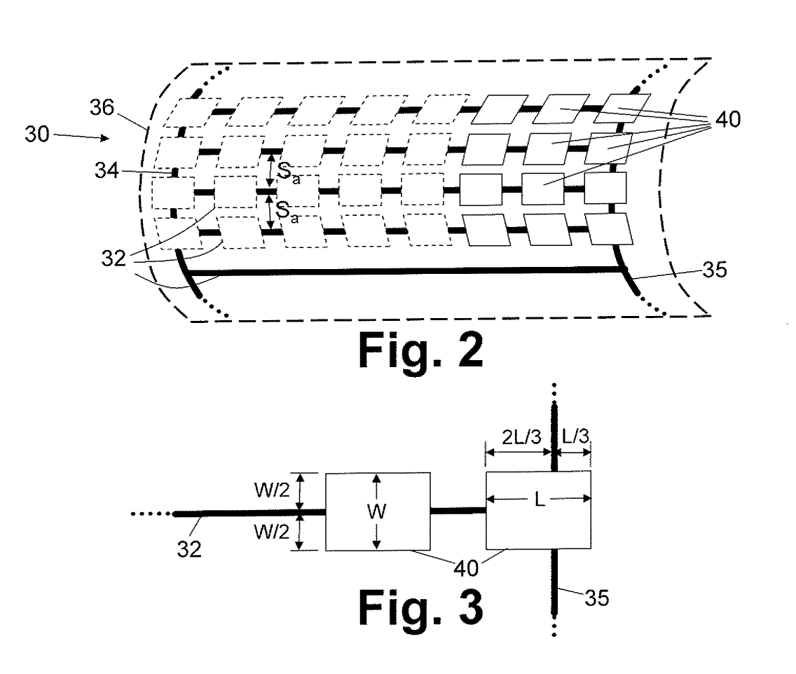

FIG. 2 diagrammatically shows a perspective view of the array of generally planar magnetic resonance receive coils and a portion of the birdcage coil of FIG. 1.

FIG. 3 diagrammatically shows selected dimensional relationships between two of the generally planar magnetic resonance receive coils and a proximate rung and end-ring of the birdcage coil.

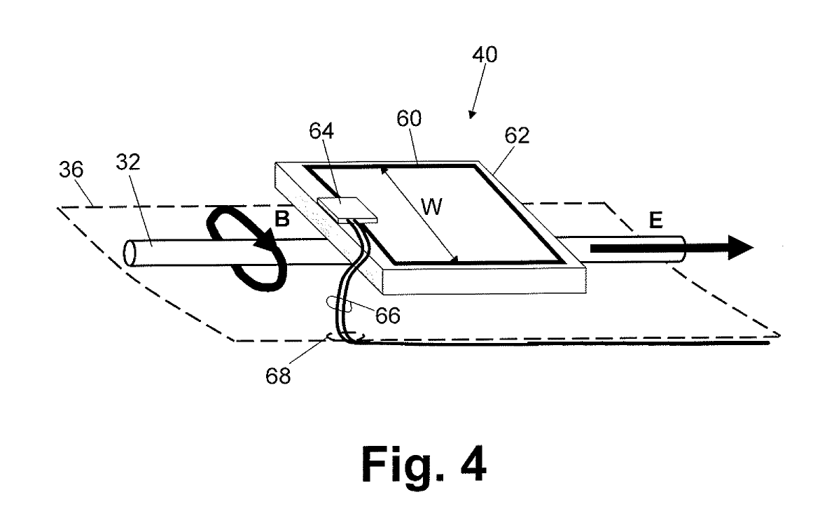

FIG. 4 diagrammatically shows a more detailed perspective view of one of the generally planar magnetic resonance receive coils and a portion of the proximate rung and radio frequency screen of the birdcage coil, along with a diagrammatic representation of electric and magnetic fields of the radio frequency energy transmitted by the birdcage coil at or near the shown portion of the proximate rung.

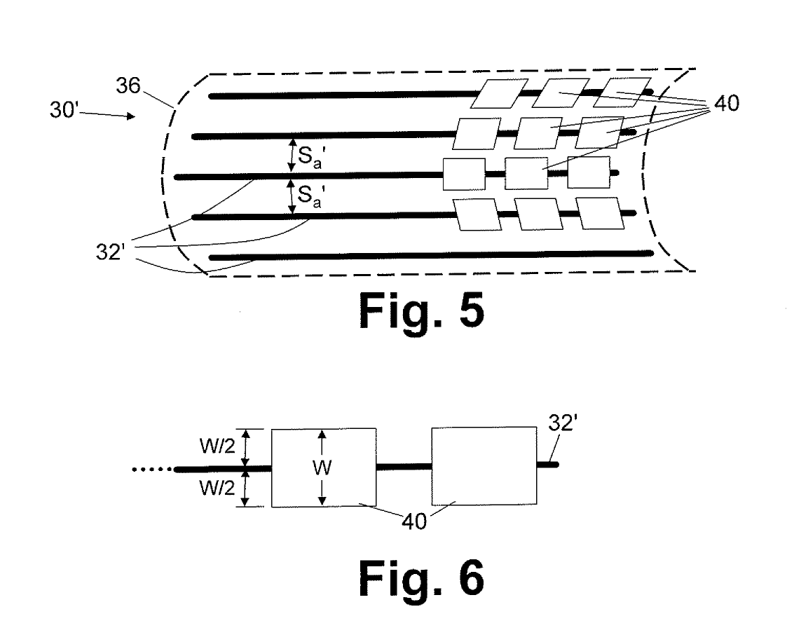

FIG. 5 diagrammatically shows a perspective view of the array of generally planar magnetic resonance receive coils and a portion of a radio frequency TEM coil that optionally replaces the birdcage coil of FIGS. 1 and 2.

FIG. 6 diagrammatically shows selected dimensional relationships between two of the generally planar magnetic resonance receive coils and a proximate rod of the TEM coil of FIG. 5.

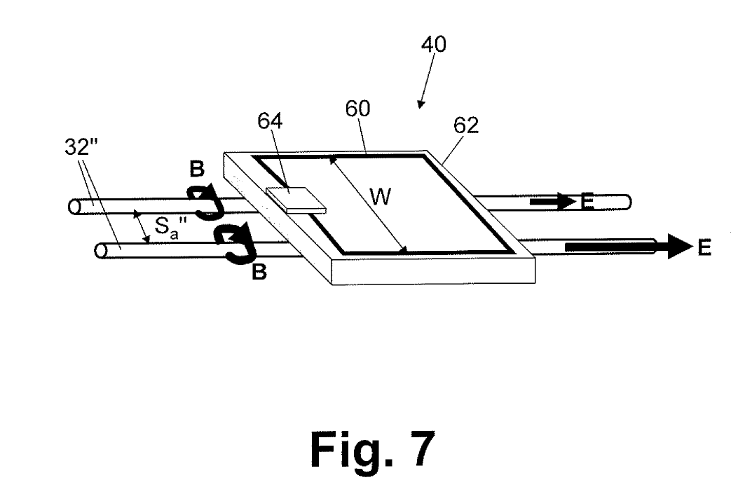

FIG. 7 diagrammatically shows a detailed perspective view of another embodiment in which the net flux through a coil loop is made small by positioning the coil substantially centered on and overlapping a proximate two neighboring rungs or rods of the transmit coil, along with a diagrammatic representation of electric and magnetic fields of the radio frequency energy transmitted by the birdcage coil at or near the shown portion of the proximate two neighboring rungs or rods.

With reference to FIG. 1, a magnetic resonance scanner system includes a main magnet 10 disposed in a scanner housing 12 and operated by a main magnet controller 14. The main magnet generates a static magnetic field in an examination region disposed in a scanner bore 14. In FIG. 1, a human subject 16 is disposed in the scanner bore 14 so as to undergo magnetic resonance imaging, spectroscopy, or the like. The main magnet 10 may be a superconducting magnet disposed suitable cryogenic refrigeration 18, or may be a resistive magnet optionally cooled by water cooling or the like. In various embodiments, the main magnet 10 may produce a static magnetic field at, for example, 0.23 Tesla, 1.5 Tesla, 3 Tesla, 7 Tesla, or so forth. Magnetic field gradient coils 20 are disposed on or, more typically, in the scanner housing 12. For example, the magnetic field gradient coils 20 may be configured to selectably superimpose x, y, and z magnetic field gradients, or various combinations thereof, on the static magnetic field in the examination region. The magnetic field gradient coils 20 are suitably operated by magnetic field gradient controllers 22. The scanner bore 14 is defined or delineated by the inner surface of a bore wall 24 facing the examination region.

With continuing reference to FIG. 1 and with further reference to FIG. 2, a radio frequency birdcage coil 30 is disposed on or in the scanner housing 12. The birdcage coil 30 includes a plurality of parallel rungs 32 arranged generally parallel to each other and to the cylindrical axis of the bore 14, and spaced apart azimuthally by a spacing Sₙ (labeled in FIG. 2) around the bore 14. The rungs 32 are terminated at each end by end rings 34, 35 arranged generally transverse to the rungs 32. The rungs 32 and end rings 34, 35 are electrical conductors, such as copper bars, copper traces or striplines disposed on a dielectric surface, or so forth. In the embodiment of FIG. 1, the rungs 32 and end rings 34, 35 are copper bars, traces, or striplines disposed on the inner surface of the bore wall 24 facing the examination region; however, in other embodiments the rungs and end-rings may be disposed on the outer surface of the bore wall, i.e., the surface facing away from the examination region, or may be disposed on a dedicated dielectric former inside the scanner housing 12, or may be disposed on a dielectric former that also supports one or more of the magnetic field gradient coils 20, or so forth. The rungs 32 and end-rings 34, 35 are conductively coupled to define a conductive structure that is resonant at the magnetic resonance frequency, and this structure optionally includes lumped or distributed capacitive, inductive, and/or resistive elements (not shown) to tune the resonant frequency of the structure. Although two end rings 34, 35 are shown, in some contemplated embodiments a third or more end rings may be included; for example, a third end ring may provide tuning to match the magnetic resonance frequency. The birdcage coil 30 further includes a radio frequency screen 36 substantially surrounding the rungs 32. The radio frequency screen 36 is suitably a metallic mesh or other conductive structure that is permeable by the magnetic fields and magnetic field gradients generated by the main magnet 10 and gradient coils 20, but that is substantially impenetrable by fields at the magnetic resonance frequency. The radio frequency screen 36 may, for example be disposed on the outer surface of the bore wall facing away from the examination region, or may be disposed on the outer surface of a dedicated dielectric former (for example, the rungs and end-rings may be disposed on the inner surface of a dedicated cylindrical dielectric former and the screen disposed on the outer surface of said dielectric former), or the screen 36 may be disposed on a dielectric former that also supports the gradient coils 20, or so forth.

The radio frequency birdcage coil 30 operates as a transmitter to transmit radio frequency energy at or near the magnetic resonance frequency into the examination region. In operation, the structure defined by the rungs 32 and end-rings 34, 35 define a quadrature volume resonator that is selectively energized by a radio frequency transmitter 38 at the magnetic resonance frequency to generate a B, field in the examination region at the magnetic resonance frequency, so as to excite magnetic resonance in the subject 16 (or at least in the portion of the subject 16 disposed in the examination region). Optionally, during such radio frequency excitation the magnetic field gradient coils 20 apply a slice- or slab-selective magnetic field gradient to limit the radio frequency excitation to a spatial slice or slab. The radio frequency screen 36 reduces radiative energy loss by substantially keeping the generated radio frequency energy within the bore 14.

With continuing reference to FIGS. 1 and 2, a plurality of magnetic resonance receive coils 40 are disposed on the inner surface of the bore wall 24 facing the examination region. In FIGS. 1 and 2, the plurality of magnetic resonance receive coils 40 illustrate twelve receive coils 40 arranged in a 3×4 array disposed near the end of the bore 14 overlapping the head of the subject 16. In some embodiments, the array may extend along the length of the subject, as indicated in FIG. 2 by showing additional coils in phantom (using dashed lines) extending to the end-ring 34). The illustrated configurations of receive coils 40 are illustrative examples—substantially any number of receive coils can be used, and the coils can have substantially any spatial arrangement, which may or may not be a periodic array arrangement. In some embodiments, the receive coils are arranged to encircle the subject 16. A radio frequency receiver 42 with a plurality of receive channels is coupled with the plurality of magnetic resonance receive coils 40 to perform a parallel imaging technique, such as SENSE or SMASH imaging. Alternatively or additionally, the plurality of magnetic resonance receive coils 40 may be used in conjunction with the radio frequency receiver 42 to perform magnetic resonance spectroscopy or another magnetic resonance technique.

For imaging, a suitable magnetic resonance sequence is executed under the control of a scanner controller 44, such as for example applying a radio frequency excitation pulse or pulse packet using the excitation system 30, 38 in conjunction with slice- or slab-selective magnetic field gradients applied by the gradient system 20, 22, performing phase encoding along a phase-encoding direction using phase-encoding magnetic field gradients applied by the gradient system 20, 22, and performing spatially encoded readout using the plurality of magnetic resonance receive coils 40 and the radio frequency receiver 42 operating in conjunction with a readout encoding magnetic field gradient applied by the gradient system 20, 22. The resulting spatially encoded magnetic resonance data are stored in a data buffer 46, and are reconstructed by a reconstruction processor 50 using a suitable reconstruction technique comporting with the type of spatial encoding used in the magnetic resonance data acquisition. For example, if the spatial encoding is Cartesian including mutually transverse slice-selective, phase-encoding, and readout-encoding magnetic field gradients, then a Fourier transform reconstruction algorithm is suitably applied by the reconstruction processor 50 to reconstruct the magnetic resonance data. The reconstructed image is stored in a reconstructed images memory 52, and may be viewed or rendered on a user interface 54, or printed, communicated via a hospital network or the Internet, processed, or otherwise utilized. In the illustrated embodiment, the user interface 54 additionally provides user interfacing with the scanner controller 44 to enable a radiologist or other operator to select and implement the magnetic resonance imaging sequence, spectroscopy sequence, or other desired scantling operation.

With continuing reference to FIGS. 1 and 2, the rungs 32 and end-rings 34, 35 of the radio frequency transmit coil 30, on the one hand, and the magnetic resonance receive coils 40, on the other hand, are disposed together. In the illustrated embodiment, the rungs 32 and end-rings 34, 35 of the radio frequency transmit coil 30, on the one hand, and the magnetic resonance receive coils 40, on the other hand, are both disposed on the bore wall 24. A suitable dielectric film, electrical insulation layer, spacers, or other electrical insulation is provided to electrically insulate the receive coils 40 from the transmit coil 30. In other embodiments, the transmit coil and the magnetic resonance receive coils are disposed together on or in the scanner housing, but may be mounted on separate dielectric formers or otherwise separately mounted.

A concern arises with this arrangement—by disposing the transmit coil 30 and the plurality of magnetic resonance receive coils 40 together, it may be expected that the receive coils 40 will be strongly coupled with the transmit coil 30 during radio frequency excitation. The receive coils optionally include detuning circuitry to reduce such coupling during the transmit phase—however, the close proximity of the receive coils 40 to the transmit coil 30 raises a concern that such detuning circuitry may be inadequate to protect the receive coils 40 from damage during the magnetic resonance excitation.

With reference to FIGS. 2-4, the inventor has found that, contrary to such expectation, a very low level of coupling between the receive coils 40 and the transmit coil 30 can be achieved by positioning each receive coil 30 in close proximity to and substantially centered on one of the rungs 32 of the radio frequency transmit coil 30. Thus, as shown in FIG. 3, each generally planar receive coil 40 having a width W is substantially centered on the proximate rung 32, such that the receive coil 40 extends a distance of about W/2 to either side of the rung 32. As illustrated in FIG. 4, when the receive coil 40 is in this position, the electric and magnetic fields E and B of the transmitted radio frequency energy generated by the energized transmit coil 30 are oriented substantially parallel with the plane of the generally planar magnetic resonance receive coil. Accordingly, a generally planar conductive loop 60 of one or more conductor turns disposed on a dielectric substrate 62 is oriented such that the E and B fields of the rung 32 are both generally parallel to the conductive loop 60—accordingly, the flux through the loop 60 is small resulting in weak electromagnetic coupling between the conductive loop 60 and the transmit coil 30. In FIG. 4, the conductive loop 60 is rectangular; however, the conductive loop can be substantially any shape, such as rectangular, square, oval, round, or so forth. In some embodiments, for example, the dielectric substrate 62 is a printed circuit board and the conductive loop 60 is formed of copper traces disposed on the printed circuit board. Although not shown, the conductive loop 60 may include one or more breaks that are bridged by a capacitor, inductor, or other element.

To further reduce coupling, the inventor has found that it is advantageous to have the width W of the magnetic resonance receive coil 40 in the azimuthal direction be comparable to the spacing Sₐ of the rungs 32. In the illustrated embodiment, Sₐ is slightly greater than W, so that neighboring receive coils 40 are slightly spaced apart in the azimuthal direction; however, it is also contemplated to have the receive coils meet (Sₐ=W) or overlap slightly (Sₐ<W).

With particular reference to FIG. 4, the magnetic resonance receive coil 40 further includes an electronics module 64, which may include components such as a pre-amplifier, tuning circuitry, switchable detuning circuitry for detuning the receive coil 40 during the transmit phase, impedance matching circuitry, or so forth. To minimize coupling of the electronics module 64 with the transmit coil 30, the electronics module 64 is suitably Located radially inward from the rung 32 as shown in FIG. 4, with the shortest dimension of the electronics module 64 is oriented perpendicular to the proximate rung 32 of the transmit coil 30. Moreover, cabling 66 for the receive coil 40, which may for example be a bundled cable including signal, control and supply conductors, is preferably routed on the outside of, or just on the inside of, the radio frequency screen 36 of the transmit coil 30. In FIG. 4, the cabling 66 passes through a small opening 68 in the radio frequency screen 36 and is routed on the outside of the radio frequency screen 36.

In the detailed perspective view of FIG. 4, it is seen that the receive coil 40 is closer to the examination region (i.e., closer to the center of the bore 14 for the geometry of the magnetic resonance scanner of FIG. 1) than the proximate rung 32 on which the magnetic resonance receive coil is substantially centered. However, it is also contemplated to have the receive coil further from the examination region than the proximate rung, such as having the receive coil disposed between the proximate rung and the radio frequency screen.

With particular reference to FIG. 35 in some arrangements a receive coil may also he proximate to one of the end rings. For example, FIG. 3 shows one of the receive coils 40 proximate to the end ring 35. In this case, the inventor has found that reduced coupling with the transmit coil 30 is achieved by positioning the receive coil 40 with about two-thirds of a length L of the receive coil (length L being measured parallel with the proximate rung 32) disposed on an inside of the end ring 35 relatively closer to the proximate rung 32, and about one-third of the length L of the receive coil 40 disposed on an outside of the end ring 35 relatively further from the proximate rung 32.

FIGS. 1-3 particularly relate to a transmit coil that has a birdcage configuration including the plurality of rungs 32 and the transverse end rings 34, 35. However, other types of transmit coils can be used, and the generally planar receive coils 40 suitably positioned at locations respective to the radio frequency transmit coil at which the electric and magnetic fields of the transmitted radio frequency energy are oriented substantially parallel with the plane of the receive coil.

With reference to FIGS. 5 and 6, as another example a transverse electromagnetic (TEM) coil 30′ is suitably substituted for the birdcage coil 30 of FIGS. 1-3. The TEM coil 30′ includes the radio frequency screen 36, but the rungs 32 and end rings 34, 35 of the birdcage coil 30 are replaced by rods 32′. The rods 32′ are arranged similarly to the rungs 32 of the birdcage coil 30, but the end-rings are omitted, and the ends of the rods 32′ are instead conductively coupled with the radio frequency screen 36 to provide return current paths. The coupling considerations of FIG. 4 apply to the TEM coil 32′, except that the proximate rung 32 is replaced by a proximate rod 32′ as shown in FIG. 6. By substantially centering the width W of the receive coil 40 on the rod 32′, the electric and magnetic fields E, B are generally parallel with the conductive loop 60, so that flux through the loop 60 is small and the coil 40 is weakly coupled with the TEM coil 32′. Because there are no end rings in the TEM coil 32′, a receive coil can be positioned substantially arbitrarily near the end of the proximate rod 32′, as shown in FIG. 6.

In the embodiments described with particular reference to FIGS. 2-6, each receive coil 40 is positioned substantially centered on a proximate rod 32′ or rung 32 in which case the net flux of electric and magnetic fields passing through the receive coil is small. As shown in FIG. 4, the flux from the proximate rung is substantially parallel with the coil loop 60 and hence does not contribute flux through the coil loop 60. At the periphery, the closed-loop nature of the B field means that the flux contributions through the loop 60 on either side of the rung 32 are not perfectly parallel so that there is some flux through the loop 60 however, this peripheral flux on opposite sides of the rung 32 substantially cancel out so that the net flux from the peripheral contributions is still small. There may also be flux contributions from other rungs of the birdcage coil 30; however, these other rungs are further away from the conductive loop 60 and hence make relatively small contributions to the flux through the loop 60. While FIG. 4 references the birdcage coil 30, the situation is analogous for loops centered on rods 32′ of the TEM coil 30′ as shown in FIG. 6, and again the net flux through the loop 60 is small.

With reference to FIG. 7, in some cases it may be difficult to center the loop 60 on a single rung or rod 32″ (it is to be appreciated that the elements 32″ in FIG. 7 may be either rungs of a birdcage coil or rods of a TEM coil). In FIG. 7, for example, the transmit coil has closely-spaced rungs or rods 32″, such that the spacing Sa^{t} of the rods or rungs 32″ is smaller than the width W of the coil 40. Accordingly, it is not possible to center the coil 40 on any one of the rungs or rods 32″. To keep the flux through the loop 60 small, the coil 40 is instead positioned overlapping and substantially centered on two (as shown in example FIG. 7) or more neighboring rungs or rods 32″. In this arrangement, the flux from the proximate rungs or rods 32″ is substantially parallel with the coil loop 60 and hence does not contribute flux through the coil loop 60. At the sides of each rung or rod 32″, the non-parallel peripheral flux components substantially cancel out due to the overlap of the coil loop 60, so that the net flux from the peripheral contributions of the rungs or rods 32″ is still small. While in FIG. 7 two rungs or rods 32″ are overlapped, it will be appreciated that similar flux canceling is achieved if the coil 40 overlaps and is substantially centered on three, four, or more rungs or rods.

In the illustrated embodiments, the receive coils 40 are positioned respective to the radio frequency transmit coil such that a net flux of electric and magnetic fields passing through the receive coil is small. However, if the electronics module 64 includes detuning circuitry that is sufficient by itself to adequately decouple the receive coil 40 from the transmit coil during the transmit phase of the magnetic resonance sequence, then the receive coils 40 can be placed on the bore wall 24 positioned arbitrarily respective to the rungs or rods of the birdcage or TEM coil 30, 30′. For example, a coil could be placed between and not overlapping two neighboring rods or rungs, in which case the net flux through the coil loop during the transmit phase is not small but does not significantly energize the coil due to the effectiveness of the detuning circuitry.

In the illustrated embodiments, the receive coils 40 and transmit coil 30, 30′ are disposed together on or in the scanner housing 12, and the receive coils 40 are positioned respective to the transmit coil 30, 30′ such that a net flux of electric and magnetic fields passing through the receive coil is small. Such a relative arrangement between the transmit coil and receive coils is not limited to embodiments in which the coils 30, 30′, 40 are disposed on or in the scanner housing 12. For example, in contemplated head coil embodiments, an insertable head coil includes a dedicated insertable former shaped to fit over the patient's head and supporting both a birdcage or TEM transmit coil and an array of generally planar receive coil loops. In such a head coil, the receive coil loops are suitably positioned respective to the transmit coil 30, 30′ such that a net flux of electric and magnetic fields passing through the receive coil is small, for example by positioning each magnetic resonance receive coil to overlap and be positioned substantially centered on a proximate one rod or rung or proximate plurality of neighboring rods or rungs of the birdcage or TEM transmit coil.

Moreover, while in the illustrated embodiments the generally planar coils 40 are receive coils provided along with a separate and distinct transmit coil 30, 30′, in other embodiments the generally planar coils 40 may be transmit/receive coils arranged two-dimensionally over the bore wall 24 to define a transmit/receive array. In such embodiments, the separate and distinct transmit coil 30, 30′ is suitably omitted.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A magnetic resonance scanner comprising:
a radio frequency transmit coil including a plurality of parallel rods or rungs at least partially surrounding an examination region, the radio frequency transmit coil being configured to transmit radio frequency energy into the examination region at or near a magnetic resonance frequency; and
a plurality of magnetic resonance receive coils disposed with the radio frequency transmit coil, each magnetic resonance receive coil overlapping and being positioned substantially centered on a proximate one rod or rung or proximate plurality of neighboring rods or rungs of the radio frequency transmit coil.

2. The magnetic resonance scanner as set forth in claim 1, wherein the radio frequency transmit coil is disposed on or in a magnetic resonance scanner housing concentric with a magnetic resonance scanner bore, and the magnetic resonance receive coils are disposed on or in the magnetic resonance scanner housing.

3. The magnetic resonance scanner as set forth in claim 1, wherein the radio frequency transmit coil is disposed concentric with a magnetic resonance scanner bore, and the magnetic resonance receive coils are disposed on a bore wall.

4. The magnetic resonance scanner as set forth in claim 1, wherein the magnetic resonance receive coils are disposed on a surface of the bore wall facing the examination region.

5. The magnetic resonance scanner as set forth in claim 1, wherein each magnetic resonance receive coil is closer to the examination region than the proximate one or neighboring plurality of rods or rungs on which the magnetic resonance receive coil is substantially centered.

6. The magnetic resonance scanner as set forth in claim 1, wherein the radio frequency transmit coil is one of:
a TEM coil (30′) including the plurality of parallel rods arranged to define a cylinder surrounding the examination region and further including a radio frequency screen substantially surrounding the plurality of parallel rods and conductively coupled with the ends of the rods, and
a birdcage coil including the plurality of parallel rungs arranged to define a cylinder surrounding the examination region and further including end rings disposed at ends of the plurality of parallel rungs and conductively coupled with the rungs.

7. The magnetic resonance scanner as set forth in claim 6, wherein the radio frequency transmit coil is said birdcage coil, and at least one magnetic resonance receive coil of the plurality of magnetic resonance receive coils is positioned with about two-thirds of the length of the magnetic resonance receive coil disposed on an inside of the one of the end rings relatively closer to the proximate one or neighboring plurality of rungs on which it is substantially centered and about one-third of the length of the magnetic resonance receive coil disposed on an outside of the end ring relatively further from the proximate one or neighboring plurality of rungs on which it is substantially centered.

8. The magnetic resonance scanner as set forth in claim 1, wherein each magnetic resonance receive coil includes a generally planar conductive loop of one or more conductor turns having a rectangular, oval, or round shape.

9. The magnetic resonance scanner as set forth in claim 8, wherein the generally planar conductive loop is operatively coupled with an electronics module including at least a pre-amplifier, the electronics module having a shortest dimension oriented generally transverse to the proximate one or neighboring plurality of rods or rungs on which the magnetic resonance receive coil is substantially centered.

10. The magnetic resonance scanner as set forth in claim 1, wherein the radio frequency transmit coil further includes a radio frequency screen substantially surrounding the plurality of parallel rods or rungs, the scanner further including:
cabling associated with the plurality of magnetic resonance receive coils, the cabling being routed outside of or along an inside surface of the radio frequency screen.

11. The magnetic resonance scanner as set forth in claim 1, further including:
a main magnet generating a static magnetic field in the examination region; and
a gradient system configured to selectably superimpose magnetic field gradients on the static magnetic field in the examination region.

12. A magnetic resonance scanner comprising:
a scanner housing defining a bore having a bore wall, an examination region being located within the bore;
a main magnet disposed in the scanner housing and generating a static magnetic field in the examination region;
magnetic field gradient coils configured to selectably superimpose magnetic field gradients on the static magnetic field in the examination region; and
a plurality of generally planar magnetic resonance coil loops disposed on or in the bore wall.

13. The magnetic resonance scanner as set forth in claim 12, further comprising:
a radio frequency transmit coil including a plurality of parallel rods or rungs disposed on or in the scanner housing, the radio frequency transmit coil being configured to transmit radio frequency energy into the examination region at or near a magnetic resonance frequency.

14. The magnetic resonance scanner as set forth in claim 13, wherein each magnetic resonance coil loop is positioned substantially centered on one of the rods or rungs of the radio frequency transmit coil.

15. The magnetic resonance scanner as set forth in claim 13, wherein each magnetic resonance coil loop overlaps and is positioned substantially centered on two or more neighboring rods or rungs of the radio frequency transmit coil.

16. The magnetic resonance scanner as set forth in claim 13, wherein the radio frequency transmit coil further includes end-rings disposed at ends of the rungs, and at least one magnetic resonance coil loop of the plurality of generally planar magnetic resonance coil loops is positioned with about two-thirds of the length of the magnetic resonance coil loop disposed on a side of the one of the end rings relatively closer to the examination region and about one-third of the length of the magnetic resonance coil disposed on a side of the end ring relatively further from the examination region.

17. The magnetic resonance scanner as set forth in claim 12, wherein the plurality of generally planar magnetic resonance coil loops are disposed two-dimensionally over the bore wall.

18. A magnetic resonance scanner comprising:
a radio frequency transmit coil substantially surrounding an examination region and configured to transmit radio frequency energy at or near a magnetic resonance frequency into the examination region; and
a plurality of substantially planar magnetic resonance receive coils arranged close to the radio frequency transmit coil, each generally planar magnetic resonance receive coil being positioned respective to the radio frequency transmit coil such that a net flux of electric and magnetic fields passing through the receive coil is small.

19. The magnetic resonance scanner as set forth in claim 18, wherein the radio frequency transmit coil is a birdcage or TEM coil, and each substantially planar magnetic resonance receive coil is substantially centered on a proximate rung or rod of the birdcage or TEM coil with the plane of the substantially planar magnetic resonance receive coil arranged generally parallel with the proximate rung or rod.

20. The magnetic resonance scanner as set forth in claim 18, wherein the radio frequency transmit coil is a birdcage or TEM coil, and each substantially planar magnetic resonance receive coil is substantially centered on and overlaps a plurality of neighboring rungs or rods of the birdcage or TEM coil with the plane of the substantially planar magnetic resonance receive coil arranged generally parallel with the proximate rung or rod.
